(19) United States
(12) Patent Application Publication
(10) Pub. No.: US 2019/0079390 A1
(43) Pub. Date: Mar. 14, 2019

(54) IMPRINT APPARATUS AND IMPRINT METHOD

(71) Applicant: TOSHIBA MEMORY CORPORATION, Tokyo (JP)

(72) Inventors: Kazuya FUKUHARA, Suginami Tokyo (JP); Masaki MITSUYASU, Yokohama Kanagawa (JP); Masato SUZUKI, Yokohama Kanagawa (JP)

(21) Appl. No.: 15/905,308

(22) Filed: Feb. 26, 2018

(30) Foreign Application Priority Data
Sep. 11, 2017 (JP) 2017-174377

(51) Int. Cl. G03F 7/00

(52) U.S. Cl. CPC G03F 7/0002

(57) ABSTRACT

An imprint apparatus includes a substrate support, a template support, and a plurality of independent pressing members. The substrate support is configured to secure a substrate having a transfer target member thereon. The template support has a pressing member side and a template holding side for holding a template, in which a pattern to be transferred to the transfer target material is provided. The plurality of independent pressing members is contactable with the template support, and each pressing member is disposed at a different position on the pressing member side of the template support.

### CROSS-REFERENCE TO RELATED APPLICATION

This application is based upon and claims the benefit of priority from Japanese Patent Application No. 2017-174377, filed Sep. 11, 2017, the entire contents of which are incorporated herein by reference.

### FIELD

Embodiments described herein relate generally to an imprint apparatus and an imprint method.

### BACKGROUND

There are known imprint apparatuses that transfer patterns to transfer target materials such as resists. In such imprint apparatuses, patterns are transferred to transfer target materials by curing the transfer target materials with light or the like when templates in which the patterns are formed in advance are superimposed on and pressed into the transfer target material on a substrate.

In the above-described imprint apparatus, however, distortion of the template increases due to pressing in some cases, and it is difficult to transfer a pattern of the template to a transfer target member with high accuracy.

### DESCRIPTION OF THE DRAWINGS

FIG. 1 is a view illustrating an overall configuration of an imprint apparatus according to a first embodiment.

FIG. 2 is an enlarged side view illustrating the vicinity of a template holding mechanism.

FIG. 3 is a top view illustrating the template holding mechanism.

FIG. 4 is a flowchart illustrating an imprint process executed by a controller.

FIG. 5 is a top view illustrating a template holding mechanism according to a second embodiment.

FIG. 6 is a top view illustrating a template holding mechanism according to a third embodiment.

### DETAILED DESCRIPTION

Embodiments provide an imprint apparatus and an imprint method capable of transferring a pattern of a template to a transfer target member with high accuracy.

In general, according to one embodiment, an imprint apparatus includes a substrate support, a template support, and a plurality of independent pressing members. The substrate support is configured to secure a substrate having a transfer target material thereon. The template has a pressing member side and a template holding side for holding a template, in which a pattern to be transferred to the transfer target material is provided. The plurality of independent pressing members is contactable with the template support, and each pressing member is disposed at a different position on the pressing member side of the template support.

The following exemplary embodiment and modification examples may include the same constituent elements. Accordingly, common reference numerals are given to the same constituent elements and repeated description will be partially omitted. Portions in the embodiment and the modification examples may be replaced by corresponding portions in other embodiments or modification examples. Configurations, positions, or the like of portions in the embodiment and the modification examples are the same as those of other embodiments unless particularly mentioned.

### First Embodiment

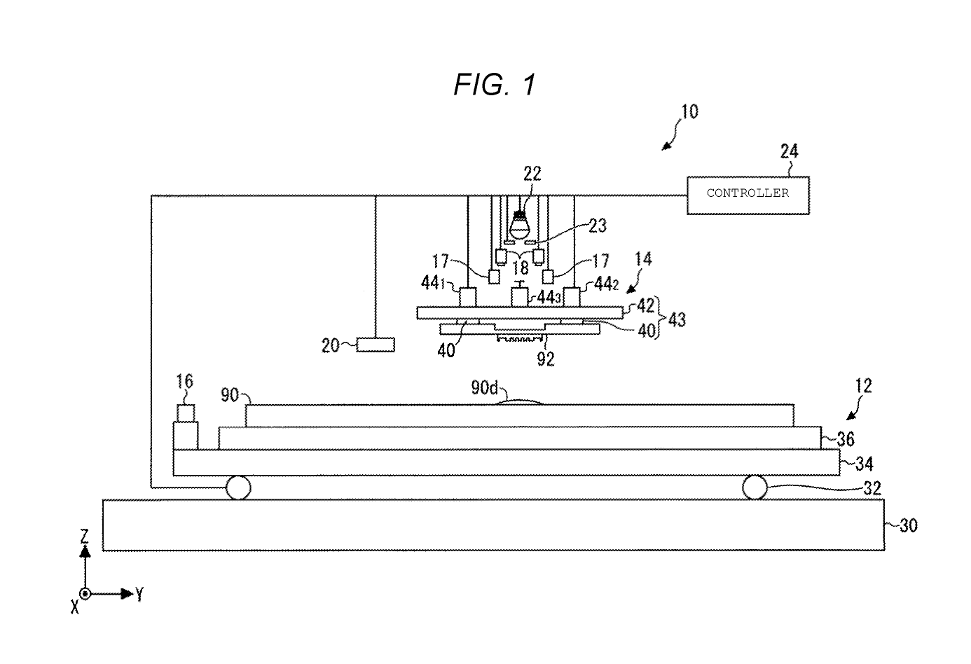

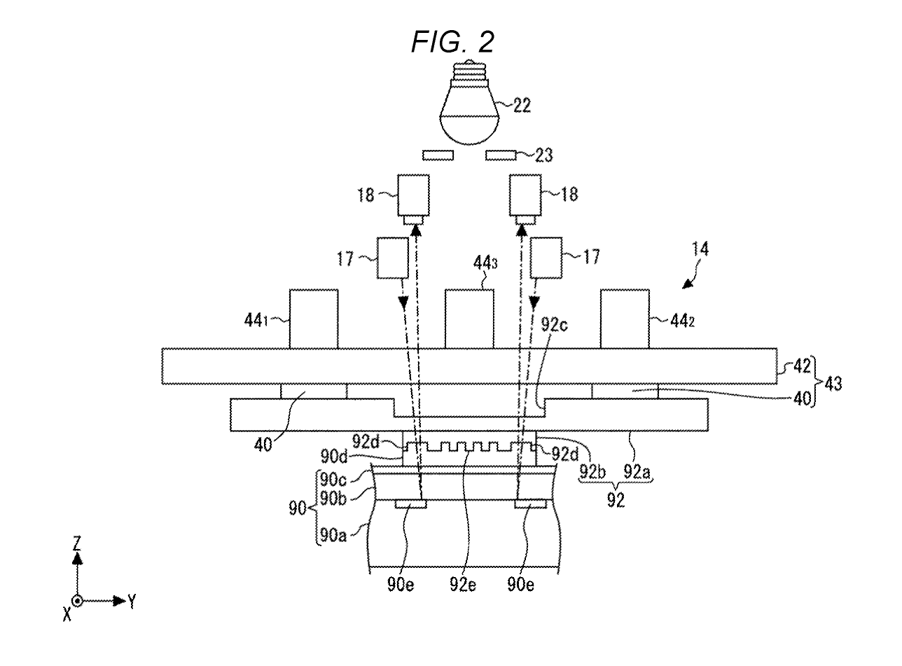

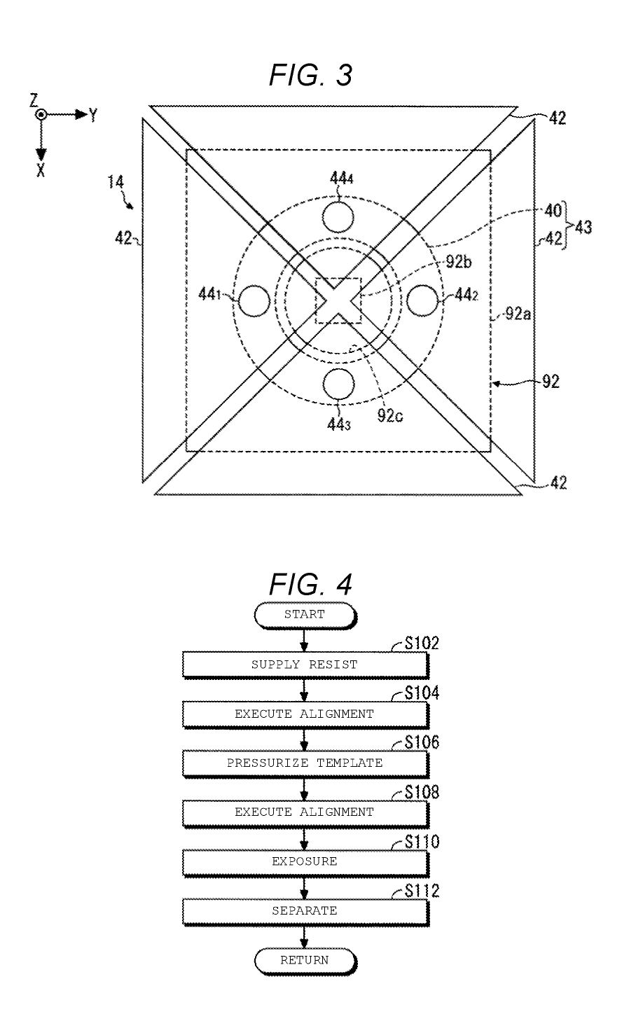

FIG. 1 is a view illustrating an overall configuration of an imprint apparatus 10 according to a first embodiment. FIG. 2 is an enlarged side view illustrating the vicinity of a template holding mechanism 14. FIG. 3 is a top view illustrating the template holding mechanism 14. In FIG. 1, directions indicated by arrows are assumed to be the XYZ directions of the imprint apparatus 10. The XY plane is, for example, a horizontal plane. The Z direction is, for example, a vertical direction and is a pressing direction of a pressing member 44 to be described below. FIG. 1 illustrates a state before a resist 90d on a substrate 90 comes into contact with a template 92. FIG. 2 illustrates a state in which the resist 90d on the substrate 90 comes into contact with the template 92. The resist 90d is an example of a transfer target material.

The imprint apparatus 10 is an apparatus that transfers a pattern (for example, a nanoscale pattern) of the template 92 on the substrate 90. For example, the imprint apparatus 10 forms the pattern in the resist 90d on the substrate 90 using an imprint method such as a light nanoimprint lithography method. As illustrated in FIGS. 1, 2, and 3, the imprint apparatus 10 includes a substrate holding mechanism 12, the template holding mechanism 14, a reference mark 16, a plurality of alignment light sources 17, a plurality of detection units 18, a supply unit 20, an exposure light source 22, an aperture 23, and a controller 24.

The substrate holding mechanism 12 holds the substrate 90 in which the resist 90d or the like is provided and moves the substrate 90 in the horizontal plane. The substrate holding mechanism 12 includes a stage surface plate 30, a driving mechanism 32, a substrate stage 34, and a substrate chuck 36.

The stage surface plate 30 is fixed to a floor, an apparatus stand, or the like.

The driving mechanism 32 is fixed to the upper surface of the stage surface plate 30. The driving mechanism 32 moves the substrate stage 34 while holding the substrate stage 34. The driving mechanism 32 moves the substrate stage 34 in two directions intersecting each other in the horizontal plane. For example, the driving mechanism 32 moves the substrate stage 34 in the X and Y directions in the horizontal plane. The driving mechanism 32 may be configured to be able to move the substrate stage 34 in a rotation direction around the vertical direction and the vertical direction.

The substrate stage 34 is a plate-shaped member. The substrate stage 34 is installed along the horizontal plane on the upper surface of the driving mechanism 32. The substrate stage 34 holds the substrate chuck 36.

The substrate chuck 36 is held on the upper surface of the substrate stage 34. The substrate chuck 36 holds the substrate 90 in which the pattern is formed. The substrate chuck 36 holds the substrate 90, for example, by vacuum chucking.

Here, the substrate 90 will be described. The substrate 90 includes a wafer 90a, an underlying pattern 90b, and a processing target layer 90c. The wafer 90a maybe, for example, a semiconductor wafer or a wafer with an insulation property. A substrate mark 90 e for alignment is formed on the wafer 90a. The underlying pattern 90b is formed on the upper surface of the wafer 90a. The processing target layer 90 c to which the resist 90d dropping from the supply unit 20 is applied is formed on the upper surface of the underlying pattern 90b. The processing target layer 90 c may be, for example, a conductive film such as a metal film, a semiconductor film, or an insulating film.

The template holding mechanism 14 moves the template 92 in the vertical direction while holding the template 92 to press the template 92 into the resist 90d on the substrate 90. The template holding mechanism 14 includes a template holding unit 43 including a template chuck 40 and a plurality of chuck holding members 42, and a plurality of pressing members 44₁, 44₂, and the like. The chuck holding member 42 is an example of a holding member. When it is not necessary to distinguish the plurality of pressing members 44₁, 44₂, and the like from each other, the plurality of pressing members 44₁, 44₂, and the like is referred to as the pressing members 44.

The template chuck 40 is formed in a ring shape to surround a counterbore 92c formed in the template 92 in a plan view. A lower surface side of the template chuck 40 holds the template 92 in which a pattern to be transferred to the resist 90d on the substrate 90 is formed. The lower surface side of the template chuck 40 is an example of one side of the template holding unit 43. The template chuck 40 holds the upper surface of the template 92 around the counterbore 92c, for example, by vacuum chucking.

The plurality of chuck holding members 42 are plate-shaped members. The plurality of chuck holding members 42 preferably have the same shape. The plurality of chuck holding members 42 have, for example, a substantially isosceles right triangle shape formed by dividing a square shape along its diagonal line in a plan view. In this case, the number of chuck holding members 42 is, for example, four. The chuck holding members 42 are disposed in a plane (for example, a horizontal plane) intersecting (for example, orthogonal to) the pressing direction. The chuck holding members 42 are preferably disposed at an equal angle interval from each other around the vertical direction. The chuck holding members 42 are disposed around the vertical direction, for example, at intervals of 90°. The template chuck 40 is fixed to the lower surfaces of the chuck holding members 42. Thus, the chuck holding members 42 hold the template chuck 40.

The pressing members 44 are directly or indirectly fixed to a top plate or a ceiling of the imprint apparatus 10. The number of pressing members 44 is preferably the same as the number of chuck holding members 42. The number of pressing members 44 is, for example, four. The pressing member 44 is, for example, an actuator that moves the chuck holding members 42, and generates a pressing force, in the vertical direction. The pressing member 44 presses the template 92 against and into the resist 90d on the substrate 90, supported by the template chuck 40 and the chuck holding member 42. Lower end portions of the pressing members 44 are disposed in a plane (for example, a horizontal plane) intersecting (for example, orthogonal to) the pressing direction. The pressing members 44 are disposed at different positions on the upper surface side of the chuck holding member 42. The upper surface side of the chuck holding member 42 is an example of the other side of the template holding unit 43. The pressing members 44 are disposed at an equal angle interval (for example, an interval of 90°) in the circumferential direction around the vertical direction with respect to each other. For example, the pressing members 44₁ and 44₂ are spaced from each other in the Y direction. The pressing members 44₃ and 44₄ are spaced from each other in the X direction. Accordingly, the direction between the pressing members 44₁ and 44₂ intersects (here, is orthogonal to) the direction between the pressing members 44₃ and 44₄. Each of the pressing members 44 is connected to one of the chuck holding members 42. In this case, one pressing member 44 preferably holds one chuck holding member 42. Accordingly, the pressing members 44 mutually independently cause different pressing forces to act on each chuck holding member 42 to press the template 92 against the substrate 90. For example, the pressing members 44₁ and 44₂ cause a first pressing force determined in advance to act on the chuck holding members 42 and the pressing members 44₃ and 44₄ cause a second pressing force determined in advance and different from the first pressing force to act on the chuck holding members 42.

Here, the template 92 will be described. The template 92 includes a template substrate 92a and a mesa portion 92b. The template substrate 92a is, for example, a plate-shaped member and has a rectangular shape (for example, a square shape) smaller than the rectangular shape obtained by combining the plurality of chuck holding members 42 in a plan view. The template 92 is formed of quartz glass which allows light for curing the resist 90d to pass therethrough. A recessed counterbore 92c is formed on the upper surface of the template substrate 92a. The counterbore 92c has, for example, a circular shape larger than the mesa portion 92b in a plan view. The mesa portion 92b is integrally provided on the lower surface of the template substrate 92a. The mesa portion 92b is formed of, for example, the same material as the template substrate 92a. A template mark 92d for alignment and a pattern 92e such as a circuit pattern with an uneven shape to be formed on the resist 90d on the substrate 90 are formed on the lower surface of the mesa portion 92b. The size of the mesa portion 92b is substantially the same as the shot region to which the pattern 92e is transferred at one time.

The reference mark 16 is a mark indicating the position of the substrate 90 on the substrate stage 34. For example, the reference mark 16 is fixed to the upper surface of the substrate stage 34. Thus, a relative position of the reference mark 16 to the substrate 90 held by the substrate chuck 36 installed in the substrate stage 34 is fixed. The reference mark 16 is used to set a reference position of the substrate 90 during alignment of the substrate 90 with the template 92 in a stage of alignment before the template 92 comes into contact with the resist 90d of the substrate 90.

The plurality of alignment light sources 17 is disposed above the template holding mechanism 14 to surround the center of the chuck holding member 42 and the template 92. The alignment light sources 17 radiate light for alignment to the substrate mark 90 e and the template mark 92d. For example, the alignment light sources 17 radiate the light for alignment so that the light penetrates through both the marks 92d and 90 e, as indicated by a dot chain line in FIG. 2 when the resist 90d and the mesa portion 92b are superimposed and the template mark 92d and the substrate mark 90 e are substantially superimposed.

The plurality of detection units 18 is disposed above the template holding mechanism 14 to surround the center of the chuck holding member 42 and the template 92. Each detection unit 18 is disposed to correspond to one of the alignment light sources 17. For example, the number of detection units 18 is preferably the same as the number of substrate marks 90 e and template marks 92d. The detection units 18 are disposed according to, for example, the positions of the substrate marks 90 e and the template marks 92d. The detection units 18 function as an alignment scope that detects the substrate marks 90 e and the template marks 92d at which the light is radiated from the alignment light sources 17. The detection units 18 are, for example, optical observation devices that include imaging devices such as digital cameras. The detection units 18 image the substrate marks 90 e and the template marks 92d and output these images to the controller 24.

The supply unit 20 is installed above the substrate 90 and the substrate holding mechanism 12. The supply unit 20 supplies and applies the resist 90d in a liquid droplet form to the shot region on the upper surface of the substrate 90 to which the pattern 92e is transferred. The resist 90d is, for example, a light curable resin.

The exposure light source 22 is disposed above the center of the chuck holding member 42 and the template 92. The exposure light source 22 is, for example, an ultraviolet radiation lamp that radiates ultraviolet light capable of curing the resist 90d. The exposure light source 22 radiates the light for curing to the resist 90d through the template 92 in contact with the resist 90d on the substrate 90 to expose the resist 90d. Thus, the exposure light source 22 cures the resist 90d.

The aperture 23 is installed between the exposure light source 22 and the chuck holding member 42. The aperture 23 allows a part of the light from the exposure light source 22 to be transmitted through the chuck holding member 42 and blocks the remaining light of the light source 22.

The controller 24 is, for example, a computer that includes a hardware processor such as a central processing unit (CPU), a memory, a hard disc drive (HDD), and the like. The controller 24 serves to overall control the imprint apparatus 10. For example, the controller 24 controls the driving mechanism 32, the alignment light sources 17, the detection units 18, the supply unit 20, the pressing member 44, the exposure light source 22, and the aperture 23.

For example, the controller 24 detects the reference mark 16 and sets the reference position of the substrate 90 on the substrate chuck 36 installed in the substrate stage 34. The controller 24 controls the driving mechanism 32 to move the substrate stage 34, and thus the substrate 90. The controller 24 controls the supply unit 20 to drop and thereby apply the resist 90d to the shot region of the substrate 90. The controller 24 acquires captured images of the substrate mark 90 e and the template mark 92d from the detection units 18 to align the positions of the substrate 90 and the template 92 when the alignment light sources 17 are caused to radiate their light. The controller 24 controls the plurality of pressing members 44 to press the template 92 against the and into the resist 90d applied to the substrate 90. Here, the controller 24 may individually control the plurality of pressing members 44 with a voltage or the like applied to the pressing members 44 such that the pressing forces of the pressing members 44 acting on the chuck holding members 42 holding the template may be different and controlled independently. The controller 24 controls a diaphragm of the aperture 23 and ON and OFF of the exposure light source 22 such that light for exposure is radiated to the shot region on the substrate 90 on which the resist 90d is applied.

Next, an imprint method by the imprint apparatus 10 will be described. FIG. 4 is a flowchart illustrating an imprint process executed by the controller 24.

In the imprint process, the controller 24 drops and applies the resist 90d to the shot region on the substrate 90 (S102). For example, the controller 24 sets the reference position of the substrate 90 based on the position of the reference mark 16. Based on the reference position of the substrate 90, the controller 24 controls the driving mechanism 32 to move the substrate 90 such that the shot region into which the pattern of the template 92 is to be subsequently transferred is located below the supply unit 20. The controller 24 controls the supply unit 20 such that the resist 90d is dropped and applied to the shot region.

As illustrated in FIG. 1, the controller 24 aligns the position of the substrate 90 so that the mesa portion 92b and the shot region of the substrate 90 to which the resist 90d is applied substantially face each other by controlling the driving mechanism 32 to move the substrate 90 based on the reference position of the substrate 90 (S104).

As illustrated in FIG. 2, the controller 24 controls the pressing member 44 such that the template 92 is moved toward the substrate 90 while bringing the mesa portion 92b into contact with, and into, the resist 90d to imprint the pattern 92e of the mesa portion 92b into the resist 90d (S106). Here, the controller 24 individually controls the pressing members 44 such that the template 92 may be pressed into the resist with different pressing forces at different locations thereof. For example, the controller 24 may cause the first pressing force acting on the chuck holding member 42 by the pressing members 44₁ and 44₂ spaced in the Y direction and the second pressing force acting on the chuck holding member 42 by the pressing members 44₃ and 44₄ spaced in the X direction to be different from each other. Thus, the shape of the template 92 in the X direction and the shape of the template 92 in the Y direction are differently deformed. Accordingly, compared to the template 92 deformed in a spherical shape when the pressing forces of all the pressing members 44 are set to be the same, the template 92 comes into contact with the resist 90d in a substantially flat state to imprint the pattern 92e.

The controller 24 aligns the substrate 90 with the template 92 when the mesa portion 92b is pressed against and into the resist 90d while coming into contact with the resist 90d (S108). For example, the controller 24 acquires the captured images of the substrate mark 90 e and the template mark 92d from the detection units 18 when the alignment light sources 17 are turned on and radiate their light. Based on the captured images, the controller 24 controls the driving mechanism 32 to move the substrate 90 such that the substrate 90 becomes aligned with the template 92.

The controller 24 exposes and cures the resist 90d with the light for exposure radiated thereon by turning on the exposure light source 22 (S110). Thus, the pattern 92e of the mesa portion 92b is transferred and formed into the resist 90d.

The controller 24 then controls the pressing member 44 such that the mesa portion 92b is separated from the resist 90d (S112).

Thereafter, the controller 24 repeats the processes subsequent to step S102 to form the pattern 92e in all of the shot regions on the substrate 90. In this way, the imprint process ends.

As described above, the imprint apparatus 10 according to the first embodiment includes the plurality of pressing members 44. Thus, the imprint apparatus 10 prevents distortion of the template 92 by causing the pressing forces of the plurality of pressing members 44 to be different and appropriately pressing the template 92 into the resist to cause the template to remain flat. As a result, the imprint apparatus 10 can reduce a difference in an overlay error of two directions (for example, the X and Y directions) of a third magnification component and can transfer and form the pattern 92e of the template 92 to the resist 90d with high accuracy. Accordingly, the imprint apparatus 10 reduces manufacturing cost and improves a yield of semiconductor devices manufactured after the pattern is formed.

The imprint apparatus 10 includes the plurality of chuck holding members 42 associated with any one of the plurality of pressing members 44. Thus, in the imprint apparatus 10, the pressing force of one pressing member 44 can be transferred to the corresponding lower chuck holding member 42 and the pressing force can be prevented from being transferred to the other chuck holding members 42. As a result, in the imprint apparatus 10, the pressing force of the plurality of pressing members 44 can be appropriately transferred to a desired region.

In the imprint apparatus 10, the first pressing force of the pressing members 44₁ and 44₂ spaced in the Y direction and the second pressing force of the pressing members 44₃ and 44₄ spaced in the X direction are set to be different. Thus, the imprint apparatus 10 can bend the shapes of the chuck holding member 42, the template chuck 40, and the template 92 in the X direction and the shapes of the chuck holding member 42, the template chuck 40, and the template 92 in the Y direction in different amounts. Accordingly, the imprint apparatus 10 can press the resist 90d with the template 92 being in a substantially flat state compared to when the template 92 is bent in the partially spherical shape with all the pressing forces being equal. As a result, the imprint apparatus 10 can transfer the pattern 92e using the mesa portion 92b in which the distortion is prevented with high accuracy.

### Second Embodiment

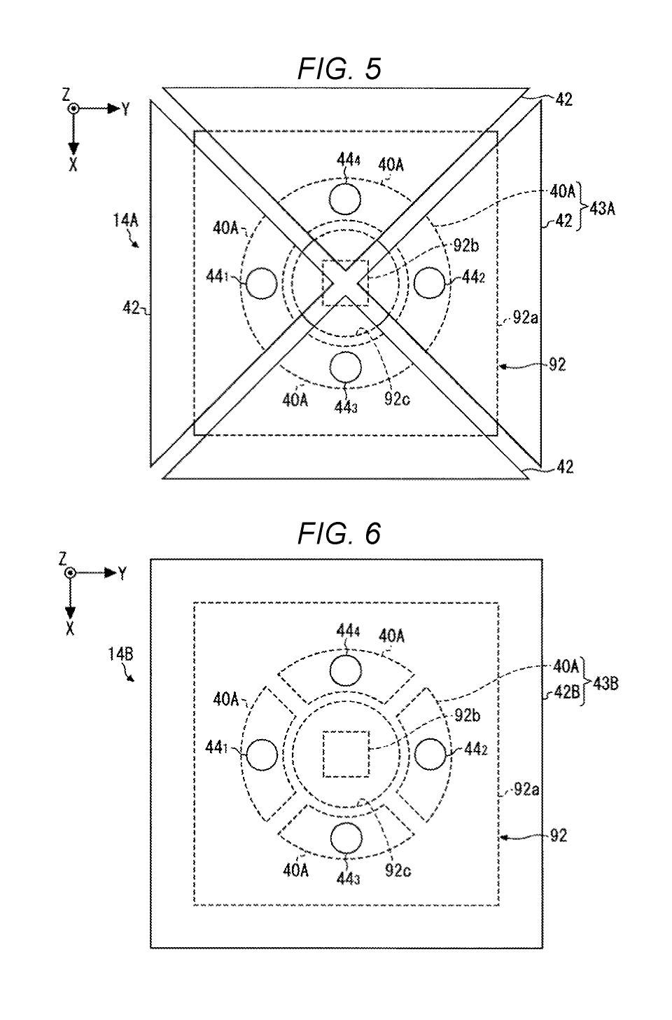

Next, a second embodiment in which a part of the above-described template holding mechanism 14 is modified will be described. FIG. 5 is a top view illustrating a template holding mechanism 14A according to the second embodiment. The template holding mechanism 14A according to the second embodiment includes a template holding unit 43A including a plurality of template chucks 40A and a plurality of chuck holding members 42 and a plurality of pressing members 44.

Each template chuck 40A is formed in, for example, a partially circular shape. The template chucks 40A are disposed in a plane (for example, a horizontal plane) intersecting (for example, orthogonal to) the pressing direction. The template chucks 40A are disposed at equal angle intervals (for example, an interval of 90°) in the circumferential direction around the vertical direction. The number of template chucks 40A is, for example, four and is the same as the numbers of chuck holding members 42 and pressing members 44. Each template chuck 40A is disposed in association with one of the chuck holding members 42 and one of the pressing members 44. Thus, each template chuck 40A is pressed by one corresponding pressing member 44 along with the chuck holding member 42. As a result, in the imprint apparatus 10 according to the second embodiment, each template chuck 40A can reduce an influence of the pressing force of the pressing member 44 installed above the template chuck 40A other than the pressing members 44.

### Third Embodiment

Next, a third embodiment in which parts of the above-described template holding mechanisms 14 and 14A are modified will be described. FIG. 6 is a top view illustrating a template holding mechanism 14B according to the third embodiment. The template holding mechanism 14B according to the third embodiment includes a template holding unit 43B including the plurality of template chucks 40A and one chuck holding member 42B and a plurality of pressing members 44.

The chuck holding member 42B is formed in a rectangular shape such as a square shape in a plan view. The chuck holding member 42B holds the plurality of template chucks 40A. The chuck holding member 42B is formed of an elastic material to be elastically deformed. Thus, the chuck holding member 42B can transfer the pressing force from the pressing member 44 to the lower template chuck 40A associated with the pressing member 44 and can prevent the transfer of the pressing force to the other template chucks 40A.

The dispositions, functions, numbers, shapes, and the like of the configurations according to the above-described embodiments maybe appropriately changed. The embodiments may be appropriately combined.

For example, in the above-described embodiment, the pressing forces of the pressing members 44 set to be different are caused to act on the chuck holding members 42 by the controller 24, but the pressing forces are not limited thereto. For example, the functions of the pressing members 44 may be set to be different so that the pressing forces of the pressing members 44 may be set to be different. Even in this case, the first and second pressing forces are preferably set to be different by setting the first pressing forces of the plurality of pressing members 44 spaced in the first direction (for example, the Y direction) to be identical and setting the second pressing forces of the plurality of pressing members 44 spaced in the second direction (for example, the X direction) intersecting the first direction to be identical.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An imprint apparatus, comprising:
a substrate support configured to secure a substrate having a transfer target material thereon;
a template support having a pressing member side and a template holding side for holding a template, in which a pattern to be transferred to the transfer target material is provided; and
a plurality of independent pressing members contactable with the template support, each pressing member disposed at a different position on the pressing member side of the template support.

2. The imprint apparatus according to claim 1, wherein
the template support comprises a plurality of independent template holding members disposed along a plane, and
each of the pressing members is connected to a different one of the plurality of independent template holding members.

3. The imprint apparatus according to claim 1, wherein
the template support includes a plurality of template chucks releasably securing different portions the template thereto, and
a different pressing member is associated with each one of the template chucks.

4. The imprint apparatus according to claim 3, wherein the template support includes an elastically deformable support member.

5. The imprint apparatus according to claim 1, wherein
the plurality of pressing members includes a plurality of first pressing members spaced from each other along a first direction and a plurality of second pressing members spaced from each other in a second direction intersecting the first direction,
the plurality of first pressing members are configured to provide a first pressing force to act on the template support, and
the plurality of second pressing members are configured to provide a second pressing force, different from the first pressing force, to act on the template holding unit.

6. The imprint apparatus according to claim 5, wherein the first direction and the second direction intersect at an intersection location and the first and second pressing members are alternately arranged along a circumference around the intersection location.

7. The imprint apparatus according to claim 6, wherein the first and second members are spaced equally from each other around the circumference.

8. An imprint method, comprising:
providing a substrate;
locating a transfer target material on a surface of the substrate;
providing a template support having a first side and a second, opposed side;
positioning a template, in which a pattern to be transferred to the transfer target material is formed, on the first side of a template support;
providing a plurality of independently controllable pressing members;
contacting each of the pressing members with the second side of the template support at a different location on the second side of the template support; and
pressing the template, with the plurality of independently controllable pressing members, against the transfer target material.

9. The method according to claim 8, wherein the template support comprises a template chuck and a plurality of chuck holding members.

10. The method according to claim 9, further comprising:
elastically interconnecting the chuck holding members.

11. The method according to claim 10, further comprising:
holding the template with the template chuck; and
holding the template chuck with the chuck holding members, wherein
a different one of the independently controllable pressing members is connected to each chuck holding member.

12. The method according to claim 11, further comprising:
spacing a first group of independently controllable pressing members along a first direction;
spacing a second group of independently controllable pressing members along a second direction intersecting the first direction; and
causing the first and second groups of independently controllable pressing members to press the template into the transfer target material, wherein
the pressing force of the first group of independently controllable pressing members is different than the pressing force of the second group independently controllable pressing members.

13. The method according to claim 11, wherein the first direction and the second direction intersect at an intersection location, and the first and second groups of pressing members are alternately arranged along a circumference around the intersection location.

14. The method according to claim 13, wherein the first and second members are spaced equally from each other along the circumference.

15. The method according to claim 8, wherein the template chuck has a ring shape.

16. An imprint lithography apparatus, comprising:
a substrate support comprising a substrate support surface;
a template chuck having a first surface facing the substrate support surface and a second surface;
a plurality of template chuck support members operatively connected to the second side of the template chuck; and
a plurality of pressing members, each pressing member connected to a single one of the template chuck support members.

17. The imprint lithography apparatus of claim 16, further comprising:
a controller configured to independently control each pressing member.

18. The imprint lithography apparatus of claim 16, further comprising:
an elastic member interconnecting the template chuck support members.

19. The imprint lithography apparatus of claim 16, wherein the pressing members are positioned along a circumferential path, and each pressing member is equally spaced from the pressing members adjacent thereto along the circumference.
